(19) United States
(12) Patent Application Publication
(10) Pub. No.: US 2021/0063872 A1
(43) Pub. Date: Mar. 4, 2021

(54) PATTERN-FORMING METHOD AND RADIATION-SENSITIVE COMPOSITION

(71) Applicant: JSR CORPORATION, Tokyo (JP)

(72) Inventor: Kazunori SAKAI, Tokyo (JP)

(73) Assignee: JSR CORPORATION, Tokyo (JP)

(21) Appl. No.: 17/095,796

(22) Filed: Nov. 12, 2020

Related U.S. Application Data
(63) Continuation of application No. PCT/JP2019/016189, filed on Apr. 15, 2019.
(60) Provisional application No. 62/671,029, filed on May 14, 2018.

(51) Int. Cl. G03F 7/004

(52) U.S. Cl. CPC G03F 7/0042; G03F 7/0045

(57) ABSTRACT

An object of the present invention is to provide a pattern-forming method and a radiation-sensitive composition being superior in each of sensitivity and a scum-inhibiting property. According to an aspect of the invention, a pattern-forming method includes applying directly or indirectly on a substrate a radiation-sensitive composition; exposing to an extreme ultraviolet ray or an electron beam a film formed after the applying; and developing the film exposed, wherein the radiation-sensitive composition contains: particles having a metal oxide as a principal component; a radical trapping agent; and an organic solvent. Furthermore, another aspect of the present invention is a radiation-sensitive composition containing: particles having a metal oxide as a principal component; a radical trapping agent; and an organic solvent.

### BACKGROUND OF THE INVENTION

### Field of the Invention

The present invention relates to a pattern-forming method and a radiation-sensitive composition.

### Description of the Related Art

General radiation-sensitive compositions for use in microfabrication by lithography generate an acid at a light-exposed region upon exposure to, e.g., an electromagnetic wave such as a far ultraviolet ray (for example, an ArF excimer laser beam, a KrF excimer laser beam, etc.) or an extreme ultraviolet ray (EUV), or a charged particle ray such as an electron beam (EB). A chemical reaction in which the acid serves as a catalyst causes a difference in rates of dissolution in a developer solution between light-exposed regions and light-unexposed regions, whereby a pattern is formed on a substrate. The pattern thus formed can be used as a mask or the like in substrate processing.

Miniaturization in processing techniques has been accompanied by a requirement for such radiation-sensitive compositions to have improved resist performance. To meet this requirement, types, molecular structures, and the like of polymers, acid generating agents, and other components which may be used in radiation-sensitive compositions have been investigated, and combinations thereof have been further investigated in detail (see Japanese Unexamined Patent Applications, Publication Nos. H11-125907, H8-146610, and 2000-298347).

Furthermore, improving sensitivity to, in particular, EUV or EB has been required recently. To meet this requirement, as a component of the radiation-sensitive composition, use of particles having a metal oxide as a principal component has been investigated. It is considered that such particles generate secondary electrons through absorption of EUV light or the like and that generation of an acid from an acid generating agent or the like is promoted by an action of the secondary electrons, thereby enabling the sensitivity to be improved.

### PRIOR ART DOCUMENTS

### Patent Documents

Patent Document 1: Japanese Unexamined Patent Application, Publication No. H11-125907
Patent Document 2: Japanese Unexamined Patent Application, Publication No. H8-146610
Patent Document 3: Japanese Unexamined Patent Application, Publication No. 2000-298347

### SUMMARY OF THE INVENTION

However, use of a radiation-sensitive composition in which such particles are used still fails to attain a sufficient level of sensitivity. Furthermore, in a case of forming a wide range of patterns for use in various electronic devices such as semiconductor devices, liquid crystal devices, and the like, there is a disadvantage in which scum cannot be inhibited due to a film remaining between spaces in a pattern at a time of development.

The present invention was made in view of the foregoing circumstances, and an object of the present invention is to provide a pattern-forming method and a radiation-sensitive composition being superior in sensitivity and a scum-inhibiting property.

According to an aspect of the invention made for solving the aforementioned problems, a pattern-forming method includes: applying directly or indirectly on a substrate a radiation-sensitive composition (hereinafter, may be also referred to as “(X) radiation-sensitive composition” or “radiation-sensitive composition (X)”); exposing to an extreme ultraviolet ray or an electron beam a film formed by the applying; and developing the film after the exposing, wherein the radiation-sensitive composition (X) contains: particles (hereinafter, may be also referred to as “(A) particles” or “particles (A)”) having a metal oxide as a principal component; a radical trapping agent (hereinafter, may be also referred to as “(B) radical trapping agent” or “radical trapping agent (B)”); and an organic solvent (hereinafter, may be also referred to as “(C) organic solvent” or “organic solvent (C)”).

Another aspect of the invention made for solving the aforementioned problems is a radiation-sensitive composition (the radiation-sensitive composition (X)) containing: particles (the particles (A)) having a metal oxide as a principal component; a radical trapping agent (the radical trapping agent (B)); and an organic solvent (the organic solvent (C)).

The pattern-forming method and the radiation-sensitive composition of the aspects of the present invention enable formation of a pattern in a highly sensitive manner, with scum being inhibited. Therefore, these can be suitably used for formation of fine resist patterns in lithography steps of various types of electronic devices such as semiconductor devices and liquid crystal devices, for which microfabrication is expected to progress further hereafter, and the like.

### DESCRIPTION OF THE EMBODIMENTS

### Pattern-Forming Method

The resist pattern-forming method according to one embodiment of the present invention includes: a step of applying the radiation-sensitive composition (X) directly or indirectly on a substrate (hereinafter, may be also referred to as “applying step”); a step of exposing the resist film formed by the applying step to EUV or EB (hereinafter, may be also referred to as “exposing step”); and a step of developing the film exposed (hereinafter, may be also referred to as “developing step”), wherein the radiation-sensitive composition contains: the particles (A); the radical trapping agent (B); and the organic solvent (C). The pattern-forming method of the one embodiment of the present invention enables formation of a pattern in a highly sensitive manner, with scum being inhibited. Hereinafter, each step will be described.

Applying Step

In this step, the radiation-sensitive composition (X) is applied directly or indirectly on a substrate to form a film. The radiation-sensitive composition (X) will be described below.

Radiation-Sensitive Composition

The radiation-sensitive composition (X) contains the particles (A), the radical trapping agent (B), and the organic solvent (C). The radiation-sensitive composition (X) preferably also contains a radiation-sensitive acid generating agent (hereinafter, may be also referred to as “(D) acid generating agent” or “acid generating agent (D)”), and may also contain, within a range not leading to impairment of the effects of the present invention, other component(s).

Due to the radiation-sensitive composition (X) containing the particles (A), the radical trapping agent (B), and the organic solvent (C), the sensitivity and the scum-inhibiting property are superior. Although not necessarily clarified and without wishing to be bound by any theory, the reason for achieving the aforementioned effects by the radiation-sensitive composition (X) due to involving such a constitution may be presumed, for example, as in the following. It is considered that the radical trapping agent (B) inhibits the particles (A) from, for example, undergoing a radical reaction and thereby crosslinking and unduly insolubilizing, and that as a result, the scum-inhibiting property is improved. Furthermore, it is considered that consequently, insolubility in a developer solution in light-exposed regions is uniformized, thereby improving the sensitivity. Hereinafter, each component will be described.

(A) Particles

The particles (A) are particles having a metal oxide as a principal component. The radiation-sensitive composition (X) contains a plurality of the particles (A). The “metal oxide” as referred to herein means a compound having a metal atom and an oxygen atom. The term “principal component” as referred to herein means a component having a percentage content being the highest among that of components constituting the particles, and the content is preferably a percentage content of no less than 50% by mass, and more preferably a percentage content of no less than 60% by mass. Due to the particles (A) having a metal oxide as the principal component, generation of secondary electrons through absorption of a radioactive ray is enabled, and generation of an acid through degradation of the acid generating agent (D) or the like is promoted by an action of the secondary electrons. As a result, it is possible to increase the sensitivity of the radiation-sensitive composition (X). The radiation-sensitive composition (X) enables formation of a pattern by altering solubility of the particles (A) in a developer liquid by exposing a film formed from the radiation-sensitive composition (X).

Metal Oxide

A metal atom (hereinafter, may be also referred to as “metal atom (m)”) constituting the metal oxide in the particles (A) is exemplified by a metal atom from groups 3 to 16 in the periodic table, and the like.

Examples of the metal atom from group 3 include a scandium atom, an yttrium atom, a lanthanum atom, a cerium atom, and the like.

Examples of the metal atom from group 4 include a titanium atom, a zirconium atom, a hafnium atom, and the like.

Examples of the metal atom from group 5 include a vanadium atom, a niobium atom, a tantalum atom, and the like.

Examples of the metal atom from group 6 include a chromium atom, a molybdenum atom, a tungsten atom, and the like.

Examples of the metal atom from group 7 include a manganese atom, a rhenium atom, and the like.

Examples of the metal atom from group 8 include an iron atom, a ruthenium atom, an osmium atom, and the like.

Examples of the metal atom from group 9 include a cobalt atom, a rhodium atom, an iridium atom, and the like.

Examples of the metal atom from group 10 include a nickel atom, a palladium atom, a platinum atom, and the like.

Examples of the metal atom from group 11 include a copper atom, a silver atom, a gold atom, and the like.

Examples of the metal atom from group 12 include a zinc atom, a cadmium atom, a mercury atom, and the like.

Examples of the metal atom from group 13 include an aluminum atom, a gallium atom, an indium atom, and the like.

Examples of the metal atom from group 14 include a germanium atom, a tin atom, a lead atom, and the like.

Examples of the metal atom from group 15 include an antimony atom, a bismuth atom, and the like.

Examples of the metal atom from group 16 include a tellurium atom and the like.

The metal atom (m) is preferably a metal atom from group 3 to group 15; more preferably a metal atom from group 3 to group 5, group 8 to group 10, or group 12 to group 14; still more preferably a metal atom from group 4, group 9, group 10, group 12, or group 14; and particularly preferably at least any one of a zirconium atom, a hafnium atom, a zinc atom, a tin atom, a nickel atom, and a cobalt atom.

The metal oxide may have an other atom in addition to the metal atom (m) and the oxygen atom. Examples of the other atom include a metalloid atom such as a boron atom or a silicon atom, a carbon atom, a hydrogen atom, a nitrogen atom, a phosphorus atom, a sulfur atom, a halogen atom, and the like. With regard to this point, in the case in which the metal oxide has the metalloid atom, a percentage content (% by mass) of the metalloid atom in the metal oxide is typically less than a percentage content of the metal atom (m) therein.

The lower limit of a total percentage content of the metal atom (m) and the oxygen atom in the metal oxide is preferably 30% by mass, more preferably 50% by mass, still more preferably 70% by mass, and particularly preferably 90% by mass. On the other hand, the upper limit of the total percentage content is preferably 99.9% by mass. When the total percentage content of the metal atom (m) and the oxygen atom falls within the above range, the generation of the secondary electrons by the particles (A) can be more effectively promoted, and as a result, the sensitivity and the scum-inhibiting property of the radiation-sensitive composition (X) can be further improved. It is to be noted that the total percentage content of the metal atom (m) and the oxygen atom may be 100% by mass.

The lower limit of a percentage content of the metal oxide in the particles (A) is preferably 60% by mass, more preferably 80% by mass, and still more preferably 95% by mass. Furthermore, the percentage content of the metal oxide may be 100% by mass. When the percentage content of the metal oxide falls within the above range, the sensitivity and the scum-inhibiting property of the radiation-sensitive composition (X) can be further improved. The particles (A) may contain one, or two or more types of the metal oxide.

The particles (A) are exemplified by, e.g., particles (hereinafter, may be also referred to as “particles (A1)”) derived from a metal compound having a hydrolyzable group, a metal-containing compound (hereinafter, may be also referred to as “(z) metal-containing compound” or “metal-containing compound (z)”) being a hydrolysate or hydrolytic condensation product the metal compound, or a combination thereof.

(z) Metal-Containing Compound

The metal-containing compound (z) is the metal compound (hereinafter, may be also referred to as “metal compound (I)”) having a hydrolyzable group, a hydrolysate or hydrolytic condensation product of the metal compound (I), or a combination thereof. The metal compound (I) may be used either alone of one type, or in a combination of two or more types thereof.

The hydrolyzable group is exemplified by a halogen atom, an alkoxy group, an acyloxy group, and the like.

Examples of the halogen atom include a fluorine atom, a chlorine atom, a bromine atom, an iodine atom, and the like.

Examples of the alkoxy group include a methoxy group, an ethoxy group, an n-propoxy group, an i-propoxy group, a butoxy group, and the like.

Examples of the acyloxy group include an acetoxy group, an ethylyloxy group, a propionyloxy group, a butyryloxy group, a t-butyryloxy group, a 1,1-dimethylpropylcarbonyloxy group, an n-hexylcarbonyloxy group, an n-octylcarbonyloxy group, and the like.

The hydrolyzable group is preferably the alkoxy group, and more preferably an isopropoxy group.

In the case in which the metal-containing compound (z) is the hydrolytic condensation product of the metal compound (I), the hydrolytic condensation product of the metal compound (I) may be, within a range not leading to impairment of the effects of the present invention, a hydrolytic condensation product obtained with a compound having both a metal atom and a metalloid atom and having a hydrolyzable group. In other words, the hydrolytic condensation product of the metal compound (I) may contain a metalloid atom within a range not leading to impairment of the effects of the present invention. Examples of the metalloid atom include a boron atom, a silicon atom, and the like. A percentage content of the metalloid atom in the hydrolytic condensation product of the metal compound (I) is typically less than 50 atom % with respect to a total of the metal atom and the metalloid atom in the hydrolytic condensation product. The upper limit of the percentage content of the metalloid atom with respect to the total of the metal atom and the metalloid atom in the hydrolytic condensation product is preferably 30 atom %, and more preferably 10 atom %.

Examples of the metal compound (I) include a compound (hereinafter, may be also referred to as “metal compound (I-1)”) represented by the following formula (A), and the like. Using such a metal compound (I-1) enables a stable metal oxide to be formed, and as a result, the sensitivity and the scum-inhibiting property of the radiation-sensitive composition (X) can be further improved.

LₐMY_{b} (A)

In the above formula (A), M represents the metal atom (m); L represents a ligand; a is an integer of 0 to 2, wherein in a case in which a is 2, a plurality of Ls are identical or different; Y represents a hydrolyzable group selected from a halogen atom, an alkoxy group, and an acyloxy group; and b is an integer of 2 to 6, wherein a plurality of Ys are identical or different, and L represents a ligand that does not fall under the definition of Y.

Examples of the metal atom (m) represented by M include metal atoms similar to those exemplified as the metal atom (m) constituting the metal oxide contained in the particles (A), and the like.

The ligand represented by L is exemplified by a monodentate ligand and a polydentate ligand.

Exemplary monodentate ligands include a hydroxo ligand, a carboxy ligand, an amido ligand, ammonia, and the like.

Examples of the amido ligand include an unsubstituted amido ligand (NH₂), a methylamido ligand (NHMe), a dimethylamido ligand (NMe₂), a diethylamido ligand (NEt₂), a dipropylamido ligand (NPr₂), and the like.

Exemplary polydentate ligands include ligands derived from a hydroxy acid ester, a β-diketone, a β-keto ester, a β-dicarboxylic acid ester, a hydrocarbon having a π bond, or a diphosphine, and the like.

Examples of the hydroxy acid ester include glycolic acid esters, lactic acid esters, 2-hydroxycyclohexane-1-carboxylic acid esters, salicylic acid esters, and the like.

Examples of the β-diketone include 2,4-pentanedione, 3-methyl-2,4-pentanedione, 3-ethyl-2,4-pentanedione, and the like.

Examples of the β-keto ester include acetoacetic acid esters, α-alkyl-substituted acetoacetic acid esters, β-ketopentanoic acid esters, benzoylacetic acid esters, 1,3-acetonedicarboxylic acid esters, and the like.

Examples of the β-dicarboxylic acid ester include malonic acid diesters, α-alkyl-substituted malonic acid diesters, α-cycloalkyl-substituted malonic acid diesters, α-aryl-substituted malonic acid diesters, and the like.

Examples of the hydrocarbon having a π bond include:

chain olefins such as ethylene and propylene;

cyclic olefins such as cyclopentene, cyclohexene, and norbornene;

chain dienes such as butadiene and isoprene;

cyclic dienes such as cyclopentadiene, methylcyclopentadiene, pentamethylcyclopentadiene, cyclohexadiene, and norbornadiene;

aromatic hydrocarbons such as benzene, toluene, xylene, hexamethylbenzene, naphthalene, and indene; and the like.

Examples of the diphosphine include 1,1-bis(diphenylphosphino)methane, 1,2-bis(diphenylphosphino)ethane, 1,3-bis(diphenylphosphino)propane, 2,2′-bis(diphenylphosphino)-1,1′-binaphthyl, 1,1′-bis(diphenylphosphino)ferrocene, and the like.

Examples of the halogen atom which may be represented by Y include a fluorine atom, a chlorine atom, a bromine atom, an iodine atom, and the like.

Examples of the alkoxy group which may be represented by Y include a methoxy group, an ethoxy group, a propoxy group, an isopropoxy group, an n-butoxy group, an isobutoxy group, a sec-butoxy group, a t-butoxy group, and the like.

Examples of the acyloxy group which may be represented by Y include an acetoxy group, a propionyloxy group, an n-butyryloxy group, an i-butyryloxy group, a t-butyryloxy group, a 1,1-dimethylpropylcarbonyloxy group, an n-hexylcarbonyloxy group, an n-octylcarbonyloxy group, and the like.

Y represents preferably the alkoxy group, and more preferably an isopropoxy group.

a is preferably 0 or 1, and more preferably 0. b is preferably 3 or 4, and more preferably 4. When a and b are each set to the above values, a percentage content of the metal oxide in the particles (A) increases, enabling the generation of secondary electrons by the particles (A) to be more effectively promoted. As a result, the sensitivity and the scum-inhibiting property of the radiation-sensitive composition (X) can be further improved.

The metal-containing compound (z) is preferably a metal alkoxide having been neither hydrolysed nor hydrolytically condensed.

Examples of the metal-containing compound (z) include zirconium tetra-n-butoxide, zirconium tetra-n-propoxide, zirconium tetraisopropoxide, hafnium tetraethoxide, indium triisopropoxide, hafnium tetraisopropoxide, hafnium tetrabutoxide, tantalum pentaethoxide, tantalum pentabutoxide, tungsten pentamethoxide, tungsten pentabutoxide, tungsten hexaethoxide, tungsten hexabutoxide, iron chloride, zinc diisopropoxide, zinc acetate dihydrate, tetrabutyl orthotitanate, titanium tetra-n-butoxide, titanium tetra-n-propoxide, zirconium di-n-butoxide bis(2,4-pentanedionate), titanium tri-n-butoxide stearate, bis(cyclopentadienyl)hafnium dichloride, bis(cyclopentadienyl)tungsten dichloride, diacetato[(S)-(−)-2,2′-bis(diphenylphosphino)-1,1′-binaphthyl]ruthenium, dichloro[ethylenebis(diphenylphosphine)]cobalt, titanium butoxide oligomers, aminopropyltrimethoxytitanium, aminopropyltriethoxyzirconium, 2-(3,4-epoxycyclohexyl)ethyltrimethoxyzirconium, γ-glycidoxypropyltrimethoxyzirconium, 3-isocyanopropyltrimethoxyzirconium, 3-isocyanopropyltriethoxyzirconium, triethoxymono(acetylacetonato)titanium, tri-n-propoxymono(acetylacetonato)titanium, tri-i-propoxymono(acetylacetonato)titanium, triethoxymono(acetylacetonato)zirconium, tri-n-propoxymono(acetylacetonato)zirconium, tri-i-propoxymono(acetylacetonato)zirconium, diisopropoxybis(acetylacetonato)titanium, di-n-butoxybis(acetylacetonato)titanium, di-n-butoxybis(acetylacetonato)zirconium, tri(3-methacryloxypropyl)methoxyzirconium, tri(3-acryloxypropyl)methoxyzirconium, tin tetraisopropoxide, tin tetrabutoxide, lanthanum oxide, yttrium oxide, and the like. Of these, the metal alkoxides and the metal acyloxides are preferred; the metal alkoxides are more preferred; and the alkoxides of titanium, zirconium, hafnium, tantalum, tungsten, or tin are still more preferred.

Furthermore, the particles (A) are exemplified by particles (hereinafter, may be also referred to as “particles (A2)”) containing the metal atom (m) and a ligand (hereinafter, may be also referred to as “ligand (p)”) derived from an organic acid (hereinafter, may be also referred to as “organic acid (a)”), and the like. Examples of the ligand (p) include the organic acid (a), an ion derived from the organic acid (a), and the like. The ligand (p) is considered to bind to the metal atom (m) in the particles (A2) via a coordinate bond or the like.

The “organic acid” as referred to herein means an organic compound that is acidic, and the “organic compound” as referred to herein means a compound having at least one carbon atom.

Due to the particles (A2) containing the metal compound having the metal atom (m) and a ligand being the organic acid (a), an ion derived from the organic acid (a), or the like, the sensitivity and the scum-inhibiting property of the radiation-sensitive composition (X) can be further improved. Such effects are considered to result from the organic acid (a) being present near surfaces of the particles (A2) due to an interaction with the metal atom (m), thereby improving solubility or dispersibility of the particles (A2) in a solvent.

The lower limit of a pKa of the organic acid (a) is preferably 0, more preferably 1, still more preferably 1.5, and particularly preferably 3. On the other hand, the upper limit of the pKa is preferably 7, more preferably 6, still more preferably 5.5, and particularly preferably 5. When the pKa of the organic acid (a) falls within the above range, the interaction with the metal atom (m) can be adjusted to be appropriately weak, and as a result, the sensitivity and the scum-inhibiting property of the radiation-sensitive composition (X) can be further improved. In the case of the organic acid (a) being a polyvalent acid, the pKa of the organic acid (a) as referred to herein means a primary acid dissociation constant, i.e., a logarithmic value of a reciprocal of a dissociation constant for dissociation of the first proton.

The organic acid (a) may be a low-molecular-weight compound or a high-molecular-weight compound, and in light of adjusting the interaction with the metal atom (m) to be appropriately weak, is preferably a low-molecular-weight compound. The low-molecular-weight compound as referred to herein means a compound having a molecular weight of no greater than 1,500, and the high-molecular-weight compound as referred to means a compound having a molecular weight of greater than 1,500. The lower limit of the molecular weight of the organic acid (a) is preferably 50, and more preferably 80. On the other hand, the upper limit of the molecular weight is preferably 1,000, more preferably 500, still more preferably 400, and particularly preferably 300. When the molecular weight of the organic acid (a) falls within the above range, the solubility or the dispersibility of the particles (A2) can be adjusted more appropriately, and as a result, the sensitivity and the scum-inhibiting property of the radiation-sensitive composition (X) can be further improved.

The organic acid (a) is exemplified by a carboxylic acid, a sulfonic acid, a sulfinic acid, an organic phosphinic acid, an organic phosphonic acid, a phenol, an enol, a thiol, an acid imide, an oxime, a sulfonamide, and the like.

Examples of the carboxylic acid include:

monocarboxylic acids such as formic acid, acetic acid, propionic acid, butanoic acid, pentanoic acid, hexanoic acid, heptanoic acid, octanoic acid, nonanoic acid, decanoic acid, 2-ethylhexanoic acid, oleic acid, acrylic acid, methacrylic acid, trans-2,3-dimethylacrylic acid, stearic acid, linoleic acid, linolenic acid, arachidonic acid, salicylic acid, benzoic acid, p-aminobenzoic acid, monochloroacetic acid, dichloroacetic acid, trichloroacetic acid, trifluoroacetic acid, pentafluoropropionic acid, gallic acid, and shikimic acid;

dicarboxylic acids such as oxalic acid, malonic acid, maleic acid, methylmalonic acid, fumaric acid, adipic acid, sebacic acid, phthalic acid, and tartaric acid;

carboxylic acids having no less than 3 carboxy groups such as citric acid; and the like.

Examples of the sulfonic acid include benzenesulfonic acid, p-toluenesulfonic acid, and the like.

Examples of the sulfinic acid include benzenesulfinic acid, p-toluenesulfinic acid, and the like.

Examples of the organic phosphinic acid include diethylphosphinic acid, methylphenylphosphinic acid, diphenylphosphinic acid, and the like.

Examples of the organic phosphonic acid include methylphosphonic acid, ethylphosphonic acid, t-butylphosphonic acid, cyclohexylphosphonic acid, phenylphosphonic acid, and the like.

Examples of the phenol include monovalent phenols such as phenol, cresol, 2,6-xylenol, and naphthol;

divalent phenols such as catechol, resorcinol, hydroquinone, and 1,2-naphthalenediol;

phenols having a valency of no less than 3 such as pyrogallol and 2,3,6-naphthalenetriol; and the like.

Examples of the enol include 2-hydroxy-3-methyl-2-butene, 3-hydroxy-4-methyl-3-hexene, and the like.

Examples of the thiol include mercaptoethanol, mercaptopropanol, and the like.

Examples of the imide include:

carboxylic imides such as maleimide and succinimide;

sulfonic imides such as di(trifluoromethanesulfonic acid)imide and di(pentafluoroethanesulfonic acid)imide; and the like.

Examples of the oxime include:

aldoximes such as benzaldoxime and salicylaldoxime;

ketoximes such as diethylketoxime, methylethylketoxime, and cyclohexanoneoxime; and the like.

Examples of the sulfonamide include methylsulfonamide, ethylsulfonamide, benzenesulfonamide, toluenesulfonamide, and the like.

In light of further improving the sensitivity and the scum-inhibiting property of the radiation-sensitive composition (X), the organic acid (a) is preferably the carboxylic acid, more preferably the monocarboxylic acid, and still more preferably methacrylic acid. The particles (A2) may contain one, or two or more types of the ligand (p).

The lower limit of a percentage content of the metal atom (m) in the particles (A2) is preferably 1% by mass, more preferably 5% by mass, and still more preferably 10% by mass. The upper limit of the percentage content is preferably 99% by mass, more preferably 95% by mass, and still more preferably 90% by mass. When the percentage content of the metal atom (m) in the particles (A2) falls within the above range, the sensitivity and the scum-inhibiting property of the radiation-sensitive composition (X) can be further improved.

The lower limit of a percentage content of the ligand (p) in the particles (A2) is preferably 1% by mass, more preferably 5% by mass, and still more preferably 10% by mass. On the other hand, the upper limit of the percentage content is preferably 90% by mass, more preferably 70% by mass, and still more preferably 50% by mass. When the percentage content of the ligand (p) falls within the above range, the solubility or the dispersibility of the particles (A2) can be adjusted still more appropriately, and as a result, the sensitivity and the scum-inhibiting property of the radiation-sensitive composition (X) can be further improved. The particles (A2) may contain one, or two or more types of the ligand (p).

The particles (A2) preferably further contain a ligand (hereinafter, may be also referred to as “ligand (q)”) derived from a base (hereinafter, may be also referred to as “base (b)”). The ligand (q) is exemplified by the base (b), an ion derived from the base (b), and the like. The ligand (q) is considered to bind to the metal atom (m) in the particles (A2) via a coordinate bond or the like.

The “base” as referred to herein means matter that is basic, and is exemplified by an Arrhenius base, a Broensted base, and a Lewis base.

For the base (b), a nitrogen-containing compound having a nitrogen atom having an unshared electron pair, a phosphorus-containing compound having a phosphorus atom having an unshared electron pair, and the like may be exemplified as an organic compound; and a metal hydroxide salt, a metal carbonate, and the like may be exemplified as an inorganic compound. Of these, the inorganic compound is preferred, and the nitrogen-containing compound is more preferred.

Examples of the nitrogen-containing compound include amine compounds represented by the following formula (1), and the like.

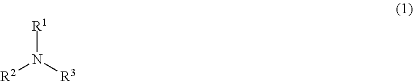

In the above formula (1), R¹, R², and R³ each independently represent a hydrogen atom or a substituted or unsubstituted monovalent hydrocarbon group having 1 to 20 carbon atoms, or two or more of R¹, R², and R³ taken together represent a ring structure having 3 to 20 ring atoms together with the nitrogen atom to which the two or more of R¹, R², and R³ bond.

The monovalent hydrocarbon group having 1 to 20 carbon atoms which may be represented by R¹, R², or R³ is exemplified by a monovalent chain hydrocarbon group having 1 to 20 carbon atoms, a monovalent alicyclic hydrocarbon group having 3 to 20 carbon atoms, a monovalent aromatic hydrocarbon group having 6 to 20 carbon atoms, and the like.

The “hydrocarbon group” as referred to herein is exemplified by a chain hydrocarbon group, an alicyclic hydrocarbon group, and an aromatic hydrocarbon group. The “hydrocarbon group” may be either a saturated hydrocarbon group or an unsaturated hydrocarbon group. The “chain hydrocarbon group” as referred to herein means a hydrocarbon group not including a cyclic structure but being constituted with only a chain structure, and is exemplified by a linear hydrocarbon group and a branched hydrocarbon group. The “alicyclic hydrocarbon group” as referred to herein means a hydrocarbon group that includes as a ring structure not an aromatic ring structure but an alicyclic structure alone, and is exemplified by a monocyclic alicyclic hydrocarbon group and a polycyclic alicyclic hydrocarbon group. With regard to this point, it is not necessary for the alicyclic hydrocarbon group to be constituted with only an alicyclic structure; it may include a chain structure in a part thereof. The “aromatic hydrocarbon group” as referred to herein means a hydrocarbon group that includes as a ring structure an aromatic ring structure. With regard to this point, it is not necessary for the aromatic hydrocarbon group to be constituted with only an aromatic ring structure; it may include a chain structure or an alicyclic structure in a part thereof.

Examples of the monovalent chain hydrocarbon group having 1 to 20 carbon atoms include:

alkyl groups such as a methyl group, an ethyl group, an n-propyl group, an i-propyl group, and a t-butyl group;

alkenyl groups such as an ethenyl group, a propenyl group, and a butenyl group;

alkynyl groups such as an ethynyl group, a propynyl group, and a butynyl group; and

the like.

Examples of the monovalent alicyclic hydrocarbon group having 3 to 20 carbon atoms include:

monocyclic alicyclic saturated hydrocarbon groups such as a cyclopentyl group and a cyclohexyl group;

monocyclic alicyclic unsaturated hydrocarbon groups such as a cyclopentenyl group and a cyclohexenyl group;

polycyclic alicyclic saturated hydrocarbon groups such as a norbornyl group, an adamantyl group, and a tricyclodecyl group;

polycyclic alicyclic unsaturated hydrocarbon groups such as a norbornenyl group and a tricyclodecenyl group; and the like.

Examples of the monovalent aromatic hydrocarbon group having 6 to 20 carbon atoms include:

aryl groups such as a phenyl group, a tolyl group, a xylyl group, a naphthyl group, and an anthryl group;

aralkyl groups such as a benzyl group, a phenethyl group, a naphthylmethyl group, and an anthrylmethyl group; and the like.

Examples of a substituent of the monovalent hydrocarbon group having 1 to 20 carbon atoms include a hydroxy group, a halogen atom, a nitro group, a cyano group, an amino group, and the like.

Examples of the ring structure having 3 to 20 ring atoms constituted by the two or more of R¹, R², and R³ taken together include:

nitrogen atom-containing aliphatic heterocyclic structures, e.g.:

azacycloalkane structures such as an azacyclopropane structure, an azacyclobutane structure, an azacyclopentane structure, and an azacyclohexane structure;

azabicycloalkane structures such as an azabicyclo[2.2.2]octane structure and an azabicyclo[2.2.1]heptane structure; and

azaoxacycloalkane structures such as an azaoxacyclohexane structure;

nitrogen atom-containing aromatic heterocyclic structures such as a pyrrole structure, an imidazole structure, a pyrazole structure, a pyridine structure, a pyrazine structure, a pyrimidine structure, a pyridazine structure, a quinolone structure, an isoquinoline structure, an acridine structure, and a phenanthroline structure; and the like.

Examples of the amine compound include:

monoamine compounds, e.g.:

tertiary amines such as triethylamine, diisopropylethylamine, tri-n-butylamine, tri-n-octylamine, N-methylpyrrolidine, and N-ethylpiperidine;

secondary amines such as pyrrolidine, piperidine, di-n-butylamine, di-n-octylamine, and morpholine; and

primary amines such as n-butylamine, n-octylamine, aniline, and toluidine;

diamine compounds such as hexamethylenediamine, N,N,N′,N′-tetramethylethylenediamine, and 1,4-diazabicyclo[2.2.2]octane;

aromatic heterocyclic amine compounds such as pyridine, pyrrole, imidazole, pyrazine, and triazine; and the like.

The lower limit of a pKb of the base (b) is preferably 2, more preferably 2.5, and still more preferably 3. The upper limit of the pKb is preferably 12, more preferably 9, and still more preferably 6. The “pKb” as referred to herein means a logarithmic value of a reciprocal of a base dissociation constant (Kb) when a temperature of the base is 25° C.

The lower limit of a boiling point of the base (b) is preferably 70° C., more preferably 80° C., still more preferably 90° C., and particularly preferably 100° C. The upper limit of the boiling point is preferably 400° C., more preferably 200° C., still more preferably 150° C., and particularly preferably 130° C.

The lower limit of a molecular weight of the base (b) is preferably 70, more preferably 80, still more preferably 90, and particularly preferably 100. The upper limit of the molecular weight is preferably 500, more preferably 400, still more preferably 300, and particularly preferably 200.

When at least any one of the pKb, the boiling point, and the molecular weight of the base (b) falls within the respective range above, the sensitivity and the scum-inhibiting property of the radiation-sensitive composition (X) can be further improved.

In the case in which the particles (A2) contain the ligand (q), the lower limit of a percentage content of the ligand (q) in the particles (A2) is preferably 1% by mass, more preferably 5% by mass, and still more preferably 10% by mass. On the other hand, the upper limit of the percentage content is preferably 90% by mass, more preferably 70% by mass, and still more preferably 50% by mass. When the percentage content of the ligand (q) falls within the above range, the sensitivity and the scum-inhibiting property of the radiation-sensitive composition (X) can be further improved. The particles (A2) may contain one, or two or more types of the ligand (q).

Other components which may be contained in the particles (A2) include an other ligand aside from the ligand (p) and the ligand (q), a metalloid atom of boron, silicon, etc., and the like. Examples of the other ligand include ligands exemplified as the monodentate ligand and the polydentate ligand which may be represented by L in the above formula (A), and the like.

The upper limit of a percentage content of the other ligand and the metalloid atom in the particles (A2) is preferably 20% by mass, and more preferably 5% by mass. The lower limit of the percentage content is, for example, 0.1% by mass.

The particles (A2) preferably include the metal atom (m) and the ligand (p); more preferably include the metal atom (m), the ligand (p), and the ligand (q); still more preferably include a metal atom from group 4, group 5, group 9, group 10, group 12, or group 14, the ligand derived from the carboxylic acid, and the ligand derived from the amine compound; and particularly preferably include the ligand derived from methacrylic acid, the ligand derived from triethylamine, and at least any one of a zirconium atom, a hafnium atom, a zinc atom, a tin atom, a nickel atom, and a cobalt atom.

### Synthesis Procedure of Particles (A)

The particles (A) can be synthesized by, for example, a below-mentioned procedure of carrying out a hydrolytic condensation reaction using the metal-containing compound (z), a below-mentioned procedure of carrying out a ligand substitution reaction using the metal-containing compound (z), and the like. The “hydrolytic condensation reaction” as referred to herein means a reaction in which a hydrolyzable group included in the metal-containing compound (z) is hydrolyzed to give —OH, and two —OHs thus obtained undergo dehydrative condensation to form —O—.

In the case in which the organic acid (a) is used for synthesizing the particles (A), the lower limit of a usage amount of the organic acid (a) with respect to 100 parts by mass of the metal-containing compound (z) is preferably 10 parts by mass, and more preferably 100 parts by mass. On the other hand, the upper limit of the usage amount of the organic acid (a) with respect to 100 parts by mass of the metal-containing compound (z) is preferably 1,000 parts by mass, more preferably 700 parts by mass, still more preferably 500 parts by mass, and particularly preferably 400 parts by mass. When the usage amount of the organic acid (a) falls within the above range, a percentage content of the organic acid (a) in the particles (A) to be obtained can be adjusted appropriately, and as a result, the sensitivity and the scum-inhibiting property of the radiation-sensitive composition (X) can be further improved.

At a time of the synthesis reaction of the particles (A), in addition to the metal compound (I) and the organic acid (a), a compound that may be the polydentate ligand which may be represented by L in the compound of the formula (1), a compound that may be a bridging ligand, etc. may also be added. The compound that may be a bridging ligand is exemplified by compounds each having a plurality of hydroxy groups, isocyanate groups, amino groups, ester groups, or amide groups, and the like.

Examples of the procedure of carrying out the hydrolytic condensation reaction using the metal-containing compound (z) include a procedure in which the hydrolytic condensation reaction of the metal-containing compound (z) is allowed in a water-containing solvent, and the like. In this case, an other compound having a hydrolyzable group may be added as necessary. The lower limit of an amount of water used for the hydrolytic condensation reaction with respect to the hydrolyzable group included in the metal-containing compound (z) and the like is preferably 0.2 times the molar amount, more preferably an equimolar amount, and still more preferably 3 times the molar amount. The upper limit of the amount of water is preferably 20 times the molar amount, more preferably 15 times the molar amount, and still more preferably 10 times the molar amount. When the amount of water used for the hydrolytic condensation reaction falls within the above range, a percentage content of the metal oxide in the particles (A) to be obtained can be increased, and as a result, the sensitivity and the scum-inhibiting property of the radiation-sensitive composition (X) can be further improved.

Examples of the procedure of carrying out the ligand substitution reaction using the metal-containing compound (z) include a procedure in which the metal-containing compound (z) and the organic acid (a) are mixed, and the like. In this case, the mixing may be conducted in a solvent, or conducted without using a solvent. Moreover, a base such as triethylamine or the like may be added as necessary in the mixing. An amount of addition of the base is, for example, no less than 1 part by mass and no greater than 200 parts by mass with respect to a total usage amount of the organic acid (a) being 100 parts by mass.

In the case in which the ligand substitution reaction is carried out by mixing the metal-containing compound (z) and the organic acid (a), the lower limit of a usage amount of the organic acid (a) with respect to 100 parts by mass of the metal-containing compound (z) is preferably 10 parts by mass, and more preferably 30 parts by mass. On the other hand, the upper limit of the usage amount of the organic acid (a) with respect to 100 parts by mass of the metal-containing compound (z) is preferably 1,000 parts by mass, more preferably 700 parts by mass, still more preferably 500 parts by mass, and particularly preferably 400 parts by mass. When the usage amount of the organic acid (a) falls within the above range, a percentage content of the organic acid (a) in the particles (A) thus obtained can be appropriately adjusted, and as a result, the sensitivity and the scum-inhibiting property of the radiation-sensitive composition (X) can be further improved.

The solvent to be used in the synthesis reaction of the particles (A) is not particularly limited, and a solvent similar to those exemplified as the organic solvent (C), described later, can be used. Of these, an alcohol solvent, an ether solvent, an ester solvent, or a hydrocarbon solvent is preferred; an alcohol solvent, an ether solvent, or an ester solvent is more preferred; a polyhydric alcohol partial ether solvent, a monocarboxylic acid ester solvent, or a cyclic ether solvent is still more preferred; and propylene glycol monoethyl ether, ethyl lactate, or tetrahydrofuran is particularly preferred.

In the case of using the organic solvent for the synthesis reaction of the particles (A), the organic solvent used may be either removed after completion of the reaction, or directly used as the organic solvent (C) in the radiation-sensitive composition (X) without removal thereof after the synthesis reaction.

The lower limit of a temperature of the synthesis reaction of the particles (A) is preferably 0° C., and more preferably 10° C. The upper limit of the temperature of the synthesis reaction is preferably 150° C., and more preferably 100° C.

The lower limit of a time period of the synthesis reaction of the particles (A) is preferably 1 min, more preferably 10 min, and still more preferably 1 hour. The upper limit of the time period is preferably 100 hrs, more preferably 50 hrs, and still more preferably 10 hrs.

The particles (A) may be obtained by washing with, e.g., a solvent such as hexane, multiple times a reaction solution obtained through the synthesis reaction using the metal-containing compound (z), the organic acid (a), and the like.

The upper limit of an average particle diameter of the particles (A) is preferably 20 nm, more preferably 15 nm, still more preferably 10 nm, particularly preferably 8 nm, further particularly preferably 5 nm, and most preferably 3 nm. The lower limit of the average particle diameter is preferably 0.5 nm, and more preferably 1 nm. When the average particle diameter of the particles (A) falls within the above range, the generation of secondary electrons in the particles (A) can be more effectively promoted and the sensitivity of the radiation-sensitive composition (X) can be further improved, and as a result, the sensitivity and the scum-inhibiting property can be further improved. The term “average particle diameter” as referred to herein means a harmonic mean particle diameter on the basis of scattered light intensity, as measured by DLS (Dynamic Light Scattering).

The lower limit of a percentage content of the particles (A) with respect to total components in the radiation-sensitive composition (X) other than the organic solvent (C) is preferably 50% by mass, more preferably 70% by mass, still more preferably 80% by mass, and particularly preferably 85% by mass. The upper limit of the percentage content is preferably 99 mol %, and more preferably 95 mol %. When the percentage content of the particles (A) falls within the above range, the sensitivity and the scum-inhibiting property of the radiation-sensitive composition (X) can be further improved. The radiation-sensitive composition (X) may contain one, or two or more types of the particles (A).

(B) Radical Trapping Agent

The radical trapping agent (B) is a compound capable of trapping radicals that have been generated, thereby enabling inhibition of radical chain reactions.

The radical trapping agent (B) is exemplified by a stable nitroxyl radical compound, a sulfide compound, a quinone compound, a phenol compound, an amine compound, a phosphite compound, and the like.

Examples of the stable nitroxyl radical compound include a piperidine-1-oxyl free radical, a 2,2,6,6-tetramethylpiperidine-1-oxyl free radical, a 4-oxo-2,2,6,6-tetramethylpiperidine-1-oxyl free radical, a 4-hydroxy-2,2,6,6-tetramethylpiperidine-1-oxyl free radical, a 4-acetamide-2,2,6,6-tetramethylpiperidine-1-oxyl free radical, a 4-maleimide-2,2,6,6-tetramethylpiperidine-1-oxyl free radical, a 4-phosphonoxy-2,2,6,6-tetramethylpiperidine-1-oxyl free radical, a 3-carboxy-2,2,5,5-tetramethylpyrrolidine-1-oxyl free radical, and the like.

Examples of the sulfide compound include phenothiazine, pentaerythritol-tetrakis(3-laurylthiopropionate), didodecyl sulfide, dioctadecyl sulfide, didodecyl thiodipropionate, dioctadecyl thiodipropionate, dimyristyl thiodipropionate, dodecyloctadecyl thiodipropionate, 2-mercaptobenzoimidazole, and the like.

Examples of the quinone compound include benzoquinone, 2,5-diphenyl-p-benzoquinone, p-toluquinone, p-xyloquinone, 2-hydroxy-1,4-naphthoquinone, and the like.

Examples of the phenol compound include hydroquinone, 4-methoxyphenol, 4-tert-butoxyphenol, catechol, 4-tert-butylcatechol, 2,5-di-tert-butylhydroquinone, 2,6-di-tert-butyl-4-methylphenol, 2,6-di-tert-butyl-m-cresol, pyrogallol, 2-naphthol, and the like.

Examples of the amine compound include N-(2,2,6,6-tetramethyl-4-piperidyl)dodecylsuccinimide, N,N′-bis(2,2,6,6-tetramethyl-4-piperidyl)butane tetracarboxylate, tetra(1,2,2,6,6-pentamethyl-4-piperidyl)butane tetracarboxylate, N,N′-di-sec-butyl-1,4-phenylenediamine, and the like.

Examples of the phosphite compound include triisodecyl phosphite, diphenyl-isodecyl phosphite, triphenyl phosphite, trinonylphenyl phosphite, and the like.

Other than the above compounds, for example, a high-molecular-weight radical trapping agent such as “Chimassorb 2020,” available from BASF SE, or “ADEKA STAB LA-68,” available from Adeka Corporation, may be used as the radical trapping agent (B).

Of these, the radical trapping agent (B) is preferably the stable nitroxyl radical compound, the sulfide compound, the quinone compound, the phenol compound, the amine compound, or a combination thereof.

The lower limit of a content of the radical trapping agent (B) with respect to 100 parts by mass of the particles (A) is preferably 0.01 parts by mass, more preferably 0.1 parts by mass, still more preferably 1 part by mass, particularly preferably 2 parts by mass, further particularly preferably 4 parts by mass, and most preferably 5 parts by mass. The upper limit of the content is preferably 50 parts by mass, more preferably 20 parts by mass, still more preferably 15 parts by mass, particularly preferably 10 parts by mass, further particularly preferably 9 parts by mass, and most preferably 8 parts by mass. When the content of the radical trapping agent (B) falls within the above range, the sensitivity and the scum-inhibiting property of the radiation-sensitive composition (X) can be further improved.

(C) Organic Solvent

The organic solvent (C) is not particularly limited as long as it is an organic solvent capable of dissolving or dispersing at least the particles (A) and the radical trapping agent (B), as well as the other component(s), such as the acid generating agent (D), which is/are contained as necessary. Either one type, or two or more types of the organic solvent (C) may be used.

The organic solvent (C) is exemplified by an alcohol solvent, an ether solvent, a ketone solvent, an amide solvent, an ester solvent, a hydrocarbon solvent, and the like.

Examples of the alcohol solvent include:

aliphatic monohydric alcohol solvents having 1 to 18 carbon atoms such as isopropyl alcohol, 4-methyl-2-pentanol, and n-hexanol;

alicyclic monohydric alcohol solvents having 3 to 18 carbon atoms such as cyclohexanol;

polyhydric alcohol solvents having 2 to 18 carbon atoms such as 1,2-propylene glycol;

polyhydric alcohol partial ether solvents having 3 to 19 carbon atoms such as propylene glycol monomethyl ether; and the like.

Examples of the ether solvent include:

dialkyl ethers solvents such as diethyl ether, dipropyl ether, dibutyl ether, dipentyl ether, diisoamyl ether, dihexyl ether, and diheptyl ether;

cyclic ether solvents such as tetrahydrofuran and tetrahydropyran;

aromatic ring-containing ether solvents such as diphenyl ether and anisole; and the like.

Examples of the ketone solvent include:

chain ketone solvents such as acetone, methyl ethyl ketone, methyl-n-propyl ketone, methyl-n-butyl ketone, diethyl ketone, methyl-iso-butyl ketone, 2-heptanone, ethyl-n-butyl ketone, methyl-n-hexyl ketone, di-iso-butyl ketone, and trimethylnonanone;

cyclic ketone solvents such as cyclopentanone, cyclohexanone, cycloheptanone, cyclooctanone, and methylcyclohexanone;

2,4-pentanedione, acetonylacetone, and acetophenone; and the like.

Examples of the amide solvent include:

cyclic amide solvents such as N,N′-dimethylimidazolidinone and N-methylpyrrolidone;

chain amide solvents such as N-methylformamide, N,N-dimethylformamide, N,N-diethylformamide, acetamide, N-methylacetamide, N,N-dimethylacetamide, and N-methylpropionamide; and the like.

Examples of the ester solvent include:

monocarboxylic acid ester solvents such as n-butyl acetate and ethyl lactate; polyhydric alcohol carboxylate solvents such as propylene glycol acetate;

polyhydric alcohol partial ether carboxylate solvents such as propylene glycol monomethyl ether acetate (PGMEA);

polyhydric carboxylic acid diester solvents such as diethyl oxalate;

carbonate solvents such as dimethyl carbonate and diethyl carbonate; and the like.

Examples of the hydrocarbon solvent include:

aliphatic hydrocarbon solvents having 5 to 12 carbon atoms such as n-pentane and n-hexane;

aromatic hydrocarbon solvents having 6 to 16 carbon atoms such as toluene and xylene; and the like.

Of these, the organic solvent (C) is preferably the ester solvent, more preferably the polyhydric alcohol partial ether carboxylate solvent, and still more preferably PGMEA.

(D) Acid Generating Agent

The acid generating agent (D) is a component which generates an acid by irradiation with a radioactive ray. A change in the solubility in a developer solution and the like of the particles (A) in the radiation-sensitive composition (X) can be further promoted by an action of the acid generated from the acid generating agent (D), and as a result, the sensitivity and the scum-inhibiting property can be further improved.

The acid generating agent (D) is exemplified by an onium salt compound, an N-sulfonyloxyimide compound, a halogen-containing compound, a diazoketone compound, and the like.

Examples of the onium salt compound include a sulfonium salt, a tetrahydrothiophenium salt, an iodonium salt, phosphonium salt, a diazonium salt, a pyridinium salt, and the like.

Examples of the sulfonium salt include triphenylsulfonium trifluoromethanesulfonate, triphenyl sulfonium nonafluoro-n-butanesulfonate, triphenylsulfonium perfluoro-n-octanesulfonate, triphenylsulfonium 2-bicyclo[2.2.1]hept-2-yl-1,1,2,2-tetrafluoroethanesulfonate, triphenylsulfonium camphorsulfonate, 4-cyclohexylphenyldiphenylsulfonium nonafluoro-n-butanesulfonate, 4-methanesulfonylphenyldiphenyl sulfonium nonafluoro-n-butanesulfonate, triphenylsulfonium 1,1,2,2-tetrafluoro-6-(1-adamantanecarbonyloxy)-hexane-1-sulfonate, triphenylsulfonium 2-(1-adamantyl)-1,1-difluoroethanesulfonate, triphenylsulfonium 2-(adamantane-1-ylcarbonyloxy)-1,1,3,3,3-pentafluoropropane-1-sulfonate, and the like.

Examples of the tetrahydrothiophenium salt include 1-(4-n-butoxynaphthalen-1-yl)tetrahydrothiophenium trifluoromethanesulfonate, 1-(4-n-butoxynaphthalen-1-yl)tetrahydrothiophenium nonafluoro-n-butanesulfonate, 1-(4-n-butoxynaphthalen-1-yl)tetrahydrothiophenium perfluoro-n-octanesulfonate, 1-(4-n-butoxynaphthalen-1-yl)tetrahydrothiophenium 2-bicyclo[2.2.1]hept-2-yl-1,1,2,2-tetrafluoroethanesulfonate, 1-(4-n-butoxynaphthalen-1-yl)tetrahydrothiophenium camphorsulfonate, 1-(6-n-butoxynaphthalen-2-yl)tetrahydrothiophenium nonafluoro-n-butanesulfonate, 1-(3,5-dimethyl-4-hydroxyphenyl)tetrahydrothiophenium nonafluoro-n-butanesulfonate, and the like.

Examples of the iodonium salt include diphenyliodonium trifluoromethanesulfonate, diphenyliodonium nonafluoro-n-butanesulfonate, diphenyliodonium perfluoro-n-octanesulfonate, diphenyliodonium 2-bicyclo[2.2.1]hept-2-yl-1,1,2,2-tetrafluoroethane sulfonate, diphenyliodonium camphorsulfonate, bis(4-t-butylphenyl)iodonium nonafluoro-n-butanesulfonate, and the like.

Examples of the N-sulfonyloxyimide compound include N-(trifluoromethylsulfonyloxy)-1,8-naphthalimide, N-(trifluoromethylsulfonyloxy)bicyclo[2.2.1]hept-5-ene-2,3-dicarboxyimide, N-(nonafluoro-n-butylsulfonyloxy)bicyclo[2.2.1]hept-5-ene-2,3-dicarboxyimide, N-(perfluoro-n-octylsulfonyloxy)-1,8-naphthalimide, N-(perfluoro-n-octylsulfonyloxy)bicyclo[2.2.1]hept-5-ene-2,3-dicarboxyimide, N-(2-bicyclo[2.2.1]hept-2-yl-1,1,2,2-tetrafluoroethylsulfonyloxy)bicyclo[2.2.1]hept-5-ene-2,3-dicarboxyimide, N-(2-(3-tetracyclo[4.4.0.1^{2,5}.1^{7,10}]dodecanyl)-1,1-difluoroethylsulfonyloxy)bicyclo[2.2.1]hept-5-ene-2,3-dicarboxyimide, N-(camphorsulfonyloxy)bicyclo[2.2.1]hept-5-ene-2,3-dicarboxyimide, and the like.

Of these, the acid generating agent (D) is preferably the onium salt compound or the N-sulfonyloxyimide compound, more preferably the sulfonium salt or the N-sulfonyloxyimide compound, still more preferably one of the triphenylsulfonium salts or the N-sulfonyloxyimide compound, and particularly preferably triphenylsulfonium nonafluoro-n-butane-1-sulfonate or N-(trifluoromethylsulfonyloxy)-1,8-naphthalimide.

In the case in which the radiation-sensitive composition (X) contains the acid generating agent (D), the lower limit of a percentage content of the acid generating agent (D) with respect to total components in the radiation-sensitive composition (X) other than the organic solvent (C) is preferably 1% by mass, more preferably 4% by mass, and still more preferably 8% by mass. The upper limit of the percentage content is preferably 40% by mass, more preferably 30% by mass, and still more preferably 20% by mass.

In the case in which the radiation-sensitive composition (X) contains the acid generating agent (D), the lower limit of a content of the acid generating agent (D) with respect to 100 parts by mass of the particles (A) is preferably 1 part by mass, more preferably 4 parts by mass, and still more preferably 8 parts by mass. The upper limit of the content is preferably 40 parts by mass, more preferably 30 parts by mass, and still more preferably 20 parts by mass.

When the content of the acid generating agent (D) falls within the above ranges, the sensitivity and the scum-inhibiting property of the radiation-sensitive composition (X) can be further improved. Either one type, or two or more types of the acid generating agent (D) may be used.

Other Component(s)

The other component(s) is/are exemplified by a radiation-sensitive radical generating agent, an acid diffusion control agent, a surfactant, and the like. The radiation-sensitive composition (X) may contain one, or two or more types of the other component(s).

Radiation-Sensitive Radical Generating Agent

The radiation-sensitive radical generating agent is a component which generates a radical by irradiation with a radioactive ray. A well-known compound may be used as the radiation-sensitive radical generating agent.

In the case in which the radiation-sensitive composition (X) contains the radiation-sensitive radical generating agent, a content of the radiation-sensitive radical generating agent may be variously set within a range not leading to impairment of the effects of the present invention.

Acid Diffusion Control Agent

The acid diffusion control agent is able to control a diffusion phenomenon in the film of the acid generated from the acid generating agent (D) and the like upon exposure, thereby serving to inhibit unwanted chemical reactions in a non-exposed region. Furthermore, storage stability and the resolution of the radiation-sensitive composition (X) are further improved. Moreover, changes in line width of the pattern caused by variation in post-exposure time delay from the exposure until a development treatment can be suppressed, thereby enabling the radiation-sensitive composition (X) to be obtained having superior process stability.

The acid diffusion control agent is exemplified by a nitrogen atom-containing compound, a photolabile base that generates a weak acid by irradiation with a radioactive ray, and the like.

Examples of the nitrogen atom-containing compound include:

amine compounds, for example,

monoamines, e.g., monoalkylamines such as n-hexylamine; dialkylamines such as di-n-butylamine; trialkylamines such as triethylamine; and aromatic amines such as aniline,

diamines such as ethylenediamine and N,N,N′,N′-tetramethylethylenediamine,

polyamines such as polyethyleneimine and polyallylamine,

polymers of dimethylaminoethylacrylamide and the like;

amide group-containing compounds such as formamide and N-methylformamide;

urea compounds such as urea and methylurea;

pyridine compounds such as pyridine and 2-methylpyridine; morpholine compounds such as N-propylmorpholine and N-(undecylcarbonyloxyethyl)morpholine;

nitrogen-containing heterocyclic compounds such as pyrazine and pyrazole;

nitrogen-containing heterocyclic compounds having an acid-labile group, such as N-t-butoxycarbonylpiperidine and N-t-butoxycarbonylimidazole; and the like.

The photolabile base is exemplified by an onium salt compound that loses acid diffusion controllability through degradation upon exposure, and the like. Exemplary onium salt compounds include triphenylsulfonium salts, diphenyliodonium salts, and the like.

Examples of the photolabile base include triphenylsulfonium salicylate, triphenylsulfonium 10-camphorsulfonate, and the like.

In the case in which the radiation-sensitive composition (X) contains the acid diffusion control agent, the lower limit of a percentage content of the acid diffusion control agent with respect to total components in the radiation-sensitive composition (X) other than the organic solvent (C) is preferably 0.1% by mass, more preferably 0.3% by mass, and still more preferably 1% by mass. The upper limit of the percentage content is preferably 20% by mass, more preferably 10% by mass, and still more preferably 5% by mass.

In the case in which the radiation-sensitive composition (X) contains the acid diffusion control agent, the lower limit of a content of the acid diffusion control agent with respect to 100 parts by mass of the particles (A) is preferably 0.1 parts by mass, more preferably 0.3 parts by mass, and still more preferably 1 part by mass. The upper limit of the content is preferably 20 parts by mass, more preferably 10 parts by mass, and still more preferably 5 parts by mass.

When the content of the acid diffusion control agent falls within the above ranges, the sensitivity and the scum-inhibiting property of the radiation-sensitive composition (X) can be further improved.

Surfactant

The surfactant is a component that exhibits an effect of improving coating properties, striation and the like. Examples of the surfactant include nonionic surfactants such as polyoxyethylene lauryl ether, polyoxyethylene stearyl ether, polyoxyethylene oleyl ether, polyoxyethylene n-octylphenyl ether, polyoxyethylene n-nonylphenyl ether, polyethylene glycol dilaurate and polyethylene glycol distearate, and the like. Examples of a commercially available product of the surfactant include KP341 (available from Shin-Etsu Chemical Co., Ltd.), Polyflow No. 75 and Polyflow No. 95 (each available from Kyoeisha Chemical Co., Ltd.), EFTOP EF301, EFTOP EF303 and EFTOP EF352 (each available from available from Tohkem Products Corporation (Mitsubishi Materials Electronic Chemicals Co., Ltd.)), Megaface F171 and Megaface F173 (each available from DIC Corporation), Fluorad FC430 and Fluorad FC431 (each available from Sumitomo 3M Limited), ASAHI GUARD AG710, Surflon S-382, Surflon SC-101, Surflon SC-102, Surflon SC-103, Surflon SC-104, Surflon SC-105 and Surflon SC-106 (each available from Asahi Glass Co., Ltd.), and the like.

### Preparation Procedure of Radiation-Sensitive Composition

The radiation-sensitive composition may be prepared, for example, by mixing the particles (A), the radical trapping agent (B), and the organic solvent (C), as well as the acid generating agent (D), the other component(s), and the like, which are added as needed, in a certain ratio, and preferably filtering a thus resulting mixture through a filter having a pore size of approximately 0.2 μm. The lower limit of a solid content concentration of the radiation-sensitive composition (X) is preferably 0.1% by mass, more preferably 0.5% by mass, still more preferably 1% by mass, and particularly preferably 3% by mass. On the other hand, the upper limit of the solid content concentration is preferably 50% by mass, more preferably 30% by mass, still more preferably 15% by mass, and particularly preferably 7% by mass. The term “solid content concentration” as referred to herein means a concentration (% by mass) of total components in the radiation-sensitive composition (X) other than the organic solvent (C).

Applying Step

Next, the applying step will be described. Specifically, the film is formed by applying the radiation-sensitive composition (X) to form a coating film such that the resulting film has a desired thickness, followed by prebaking (PB) to volatilize the organic solvent and the like in the coating film as needed. A procedure for applying the radiation-sensitive composition (X) to a substrate is not particularly limited, and an appropriate application procedure such as spin-coating, cast coating, roller coating, etc. may be employed. Examples of the substrate include a silicon wafer, a wafer coated with aluminum, and the like. It is to be noted that an organic or inorganic antireflective film may also be formed on the substrate in order to maximize potential of the radiation-sensitive composition.

The lower limit of an average thickness of the film formed in this step is preferably 1 nm, more preferably 5 nm, still more preferably 10 nm, and particularly preferably 20 nm. On the other hand, the upper limit of the average thickness is preferably 1,000 nm, more preferably 200 nm, still more preferably 100 nm, and particularly preferably 70 nm.

The lower limit of a PB temperature is typically 30° C., preferably 35° C., and more preferably 40° C. The upper limit of the PB temperature is typically 140° C., and preferably 100° C. The lower limit of a PB time period is typically 5 sec, and preferably 10 sec. The upper limit of the PB time period is typically 24 hrs, preferably 1 hr, more preferably 600 sec, and still more preferably 300 sec.

In this step, in order to preclude influences from basic impurities and the like included in an environmental atmosphere, for example, a protective film may be provided on the film formed. Furthermore, in a case of conducting liquid immersion lithography in the exposing step, as described later, a protective film for liquid immersion may be provided in order to prevent direct contact between a liquid immersion medium and the film.

Exposing Step

In this step, the film formed by the applying step is exposed to EUV or EB. Specifically, the film is irradiated with a radioactive ray through, for example, a mask having a predetermined pattern. In this step, the irradiation with the radioactive ray may be conducted through a liquid immersion medium such as water or the like, i.e., liquid immersion lithography may be adopted.

Developing Step

In this step, a developer solution is used to develop the film following the exposing step. By this step, a predetermined pattern is formed. The developer solution is exemplified by an alkaline aqueous solution, an organic solvent-containing liquid, and the like. In other words, a development procedure may be development with an alkali or development with an organic solvent.

Examples of the alkaline aqueous solution include alkaline aqueous solutions prepared by dissolving at least one alkaline compound such as sodium hydroxide, potassium hydroxide, sodium carbonate, sodium silicate, sodium metasilicate, aqueous ammonia, ethylamine, n-propylamine, diethylamine, di-n-propylamine, triethylamine, methyldiethylamine, ethyldimethylamine, triethanolamine, tetramethylammonium hydroxide (TMAH), pyrrole, piperidine, choline, 1,8-diazabicyclo-[5.4.0]-7-undecene, and 1,5-diazabicyclo-[4.3.0]-5-nonene, and the like.

The lower limit of a percentage content of the alkaline compound in the alkaline aqueous solution is preferably 0.1% by mass, more preferably 0.5% by mass, and still more preferably 1% by mass. The upper limit of the percentage content is preferably 20% by mass, more preferably 10% by mass, and still more preferably 5% by mass.

The alkaline aqueous solution is preferably an aqueous TMAH solution, and more preferably a 2.38% by mass aqueous TMAH solution.

Examples of the organic solvent in the organic solvent-containing liquid include organic solvents similar to those exemplified as the organic solvent (C) in the radiation-sensitive composition (X), and the like. Of these, the organic solvent is preferably a solvent selected from the group consisting of the alcohol solvent, the hydrocarbon solvent, and the ester solvent, and more preferably a solvent selected from the group consisting of isopropyl alcohol, 4-methyl-2-pentanol, toluene, and butyl acetate.

The lower limit of a percentage content of the organic solvent in the organic solvent-containing liquid is preferably 80% by mass, more preferably 90% by mass, still more preferably 95% by mass, and particularly preferably 99% by mass. When the percentage content of the organic solvent falls within the above range, a contrast of rates of dissolution in the developer solution between a light-exposed region and a light-unexposed region can be further improved. It is to be noted that that a component of the organic solvent-containing liquid other than the organic solvent may be, for example, water, silicone oil, or the like.

A surfactant may be added to the developer solution in an appropriate amount, as necessary. As the surfactant, for example, an ionic or nonionic fluorochemical surfactant, a silicone-based surfactant, or the like may be used.

Examples of the development procedure include: a dipping procedure in which the substrate is immersed for a given time period in the developer solution charged in a container; a puddle procedure in which the developer solution is placed to form a dome-shaped bead by way of the surface tension on the surface of the substrate for a given time period to conduct a development; a spraying procedure in which the developer solution is sprayed onto the surface of the substrate; a dynamic dispensing procedure in which the developer solution is continuously applied onto the substrate, which is rotated at a constant speed, while scanning with a developer solution-application nozzle at a constant speed; and the like.

It is preferred that, following the development, the substrate is rinsed by using a rinse agent such as water, alcohol, or the like, and then dried. A procedure for the rinsing is exemplified by: a spin-coating procedure in which the rinse agent is continuously applied onto the substrate, which is rotated at a constant speed; a dipping procedure in which the substrate is immersed for a given time period in the rinse agent charged in a container; a spraying procedure in which the rinse agent is sprayed onto the surface of the substrate; and the like.

### EXAMPLES

Hereinafter, the present invention is explained in detail by way of Examples, but the present invention is not in any way limited to these Examples.

### Synthesis of Particles (A)

### Synthesis Example 1

2.7 g of zirconium(IV) tetraisopropoxide was dissolved in 9 g of methacrylic acid, and a resulting solution was heated at 65° C. for 2 hrs. A reaction solution thus obtained was washed multiple times with hexane and then dried to give particles (A-1) containing principally a metal atom and a ligand derived from an organic acid.

### Synthesis Example 2

2.5 g of zirconium(IV) tetraisopropoxide and 1.4 g of methacrylic acid were dissolved in 40.0 g of ethyl acetate. To a resulting solution, 2.2 g of triethylamine was added dropwise, and a resulting mixture was heated at 65° C. for 10 hrs. Ethyl acetate was distilled off by vacuum concentration to give particles (A-2) containing a metal atom, a ligand derived from an organic acid, and a ligand derived from a base.

### Preparation of Radiation-Sensitive Composition

The radical trapping agent (B), the organic solvent (C), and the acid generating agent (D) used in preparing each radiation-sensitive composition are shown below.

(B) Radical Trapping Agent

B-1: hydroquinone (a compound represented by the following formula (B-1))

B-2: 4-methoxyphenol (a compound represented by the following formula (B-2))

B-3: 2,6-di-tert-butyl-4-methylphenol (a compound represented by the following formula (B-3))

B-4: 2-hydroxy-1,4-naphthoquinone (a compound represented by the following formula (B-4))

B-5: 4-oxo-2,2,6,6-tetramethylpiperidine-1-oxyl free radical (a compound represented by the following formula (B-5))

B-6: phenothiazine (a compound represented by the following formula (B-6))

B-7: N,N′-di-sec-butyl-1,4-phenylenediamine (a compound represented by the following formula (B-7))

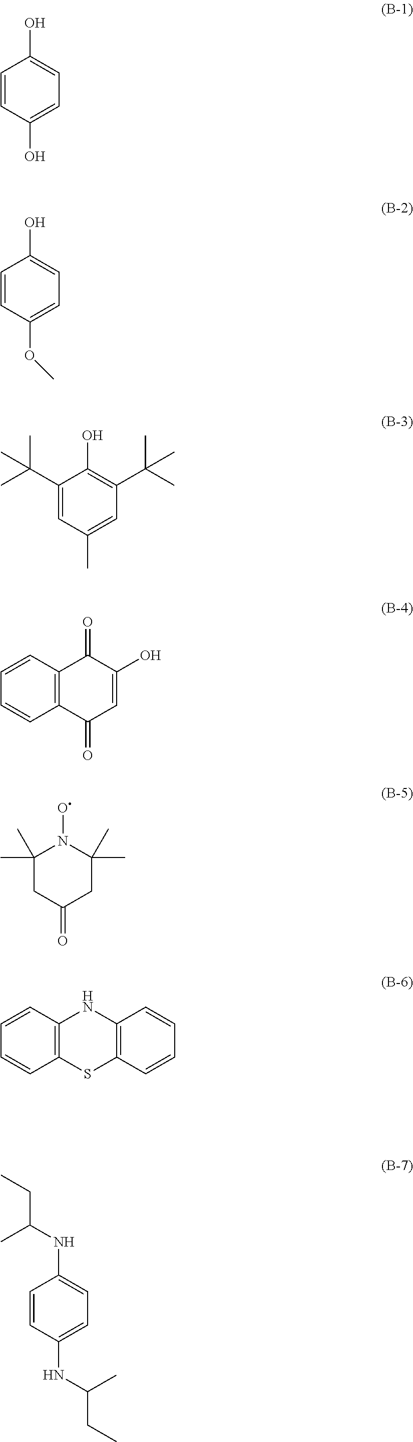

(C) Organic Solvent

C-1: propylene glycol monomethyl ether acetate (a compound represented by the following formula (C-1))

(D) Acid Generating Agent

D-1: N-(trifluoromethylsulfonyloxy)-1,8-naphthalimide (a compound represented by the following formula (D-1))

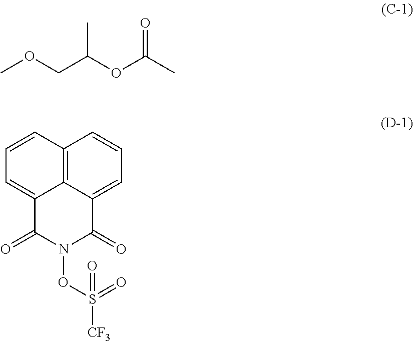

### Comparative Example 1

A mixed liquid having a solid content concentration of 5% by mass was provided by mixing 100 parts by mass of (A-1) as the particles (A), and 10 parts by mass of each of (C-1) as the organic solvent (C) and (D-1) as the acid generating agent (D). The mixed liquid thus obtained was filtered through a membrane filter having a pore size of 0.20 μm to prepare a radiation-sensitive composition (R-1). It is to be noted that in Table 1 below, “-” indicates that the “radical trapping agent (B)” has not been added.

### Example 1

A mixed liquid having a solid content concentration of 5% by mass was prepared by mixing 100 parts by mass of (A-1) as the particles (A), 20 parts by mass of (B-1) as the radical trapping agent (B), and 10 parts by mass of each of (C-1) as the organic solvent (C) and (D-1) as the acid generating agent (D). The mixed liquid thus obtained was filtered through a membrane filter having a pore size of 0.20 μm to prepare a radiation-sensitive composition (R-2).

### Examples 2 to 9

Radiation-sensitive compositions (R-3) to (R-10) were prepared by a similar operation to that of Example 1, except that each component of the type and in the content shown in Table 1 below was used.

TABLE 1

| | | | | (B) Radical | | | (D) Acid | |
|---|---|---|---|---|---|---|---|---|
| | | (A) | | trapping | | | generating | |
| | Radia- | Particles | | agent | | | agent | |
| | tion- | | con- | | con- | | | con- |
| | sen- | | tent | | tent | | | tent |
| | sitive | | (parts | | (parts | (C) | | (parts |
| | com- | | by | | by | Organic | | by |
| | position | type | mass) | type | mass) | solvent | type | mass) |
| Com- | R-1 | A-1 | 100 | — | — | C-1 | D-1 | 10 |
| parative | | | | | | | | |
| Exam- | | | | | | | | |
| ple 1 | | | | | | | | |
| Exam- | R-2 | A-1 | 100 | B-1 | 20 | C-1 | D-1 | 10 |
| ple 1 | | | | | | | | |
| Exam- | R-3 | A-1 | 100 | B-1 | 5 | C-1 | D-1 | 10 |
| ple 2 | | | | | | | | |
| Exam- | R-4 | A-1 | 100 | B-2 | 2.5 | C-1 | D-1 | 10 |
| ple 3 | | | | | | | | |
| Exam- | R-5 | A-1 | 100 | B-3 | 7.5 | C-1 | D-1 | 10 |
| ple 4 | | | | | | | | |
| Exam- | R-6 | A-1 | 100 | B-4 | 5 | C-1 | D-1 | 10 |
| ple 5 | | | | | | | | |
| Exam- | R-7 | A-1 | 100 | B-5 | 7.5 | C-1 | D-1 | 10 |
| ple 6 | | | | | | | | |
| Exam- | R-8 | A-1 | 100 | B-6 | 5 | C-1 | D-1 | 10 |
| ple 7 | | | | | | | | |
| Exam- | R-9 | A-1 | 100 | B-7 | 5 | C-1 | D-1 | 10 |
| ple 8 | | | | | | | | |
| Exam- | R-10 | A-2 | 100 | B-1 | 5 | C-1 | D-1 | 10 |
| ple 9 | | | | | | | | |

### Pattern Formation

### Comparative Example 1 and Examples 1 to 9

Each radiation-sensitive composition shown in Table 2 below was spin-coated onto a silicon wafer using a simplified spin coater, and subjected to PB under conditions of 40° C. and 60 sec to form a film having an average thickness of 50 nm. Next, patterning was conducted on the film by exposure using a vacuum ultraviolet light exposure system (exposure was conducted with NA of 0.3 and dipole illumination, through a mask having a 30 nm space and 60 nm pitch pattern). The EUV light exposure was conducted using a mask pattern for forming a line-and-space pattern (1L 1S) of 1:1, the pattern being configured with: line parts each having a line width of 50 nm; and space parts each being 50 nm formed between adjacent line parts. The film was developed with toluene, and then dried to form a negative-tone pattern.

### Evaluations

Each radiation-sensitive composition prepared as described above was evaluated on the sensitivity and the scum-inhibiting property thereof by the following methods. The results of the evaluations are shown together in Table 2 below.

Sensitivity

With regard to the pattern formation, the sensitivity was evaluated to be: “A” (extremely favorable) in a case of successful formation of the line-and-space pattern (1L 1S) at an exposure dose of no greater than 30 mJ/cm²; “B” (favorable) in a case of a failure in formation of the pattern at an exposure dose of no greater than 30 mJ/cm², and successful formation of the pattern at an exposure dose of greater than 30 mJ/cm² and no greater than 40 mJ/cm²; and “C” (unfavorable) in a case failure in formation of the pattern at an exposure dose of no greater than 40 mJ/cm².

Scum-Inhibiting Property

Spaces in the formed pattern were observed by using a scanning electron microscope to verify the presence of the film not having been peeled off by the developer solution and thus remaining in the space parts. The scum-inhibiting property was evaluated to be: “A” (favorable) in a case in which no residual film was observed; and “B” (unfavorable) in a case in which the residual film was observed.

TABLE 2

| | Radiation-sensitive | | Scum-inhibiting |
|---|---|---|---|
| | composition | Sensitivity | property |
| Comparative | R-1 | A | B |
| Example 1 | | | |
| Example 1 | R-2 | B | A |
| Example 2 | R-3 | A | A |
| Example 3 | R-4 | A | A |
| Example 4 | R-5 | A | A |
| Example 5 | R-6 | A | A |
| Example 6 | R-7 | A | A |
| Example 7 | R-8 | A | A |
| Example 8 | R-9 | A | A |
| Example 9 | R-10 | A | A |

As is clear from the results shown in Table 2 above, the pattern-forming method and the radiation-sensitive composition of the Examples enable formation of a pattern in which the sensitivity is high and the scum-inhibiting property is superior.

### INDUSTRIAL APPLICABILITY

The radiation-sensitive composition and the pattern-forming method of the embodiments of the present invention enable formation of a pattern in a highly sensitive manner, with scum being inhibited. Therefore, these can be suitably used for formation of fine resist patterns in lithography steps of various types of electronic devices such as semiconductor devices and liquid crystal devices, for which microfabrication is expected to progress further hereafter.

What is claimed is:

1. A pattern-forming method comprising:
applying directly or indirectly on a substrate a radiation-sensitive composition;
exposing to an extreme ultraviolet ray or an electron beam a film formed by the applying; and
developing the film after the exposing,
wherein
the radiation-sensitive composition comprises:
particles comprising a metal oxide as a principal component;
a radical trapping agent; and
an organic solvent.

2. The pattern-forming method according to claim 1, wherein the radical trapping agent is a stable nitroxyl radical compound, a sulfide compound, a quinone compound, a phenol compound, an amine compound, or a combination thereof.

3. The pattern-forming method according to claim 1, wherein a content of the particles with respect to total components in the radiation-sensitive composition other than the organic solvent is no less than 50% by mass.

4. The pattern-forming method according to claim 3, wherein the content of the particles with respect to total components in the radiation-sensitive composition other than the organic solvent is no less than 85% by mass.

5. The pattern-forming method according to claim 1, wherein a content of the radical trapping agent with respect to 100 parts by mass of the particles is no less than 0.01 parts by mass and no greater than 20 parts by mass.

6. The pattern-forming method according to claim 1, wherein a metal atom constituting the metal oxide is at least any one of a zirconium atom, a hafnium atom, a zinc atom, a tin atom, a nickel atom, and a cobalt atom.

7. The pattern-forming method according to claim 1, wherein the particles are derived from a compound represented by formula (A), a hydrolysis product or a hydrolytic condensation product thereof, or a combination of the same:
LₐMY_{b} (A)
wherein
in the formula (A),
M represents a metal atom constituting the metal oxide;
L represents a ligand;
a is an integer of 0 to 2, wherein in a case in which a is 2, a plurality of Ls are identical or different;
Y represents a hydrolyzable group selected from a halogen atom, an alkoxy group, and an acyloxy group;
b is an integer of 2 to 6, wherein a plurality of Ys are identical or different; and
L represents a ligand not falling under a category of Y.

8. The pattern-forming method according to claim 1, wherein the particles comprise:
a metal atom constituting the metal oxide; and
a ligand derived from an organic acid.

9. The pattern-forming method according to claim 8, wherein the particles further comprise a ligand derived from a base.

10. The pattern-forming method according to claim 8, wherein the organic acid is methacrylic acid.

11. The pattern-forming method according to claim 1, wherein a mean particle diameter of the particles is no greater than 20 nm.

12. The pattern-forming method according to claim 1, wherein the radiation-sensitive composition further comprises a radiation-sensitive acid generating agent.

13. A radiation-sensitive composition comprising:
particles comprising a metal oxide as a principal component;
a radical trapping agent; and
an organic solvent.

14. The radiation-sensitive composition according to claim 13, wherein the radical trapping agent is a stable nitroxyl radical compound, a sulfide compound, a quinone compound, a phenol compound, an amine compound, or a combination thereof.

15. The radiation-sensitive composition according to claim 13, wherein a content of the particles with respect to total components other than the organic solvent is no less than 50% by mass.

16. The radiation-sensitive composition according to claim 15, wherein a content of the particles with respect to total components other than the organic solvent is no less than 85% by mass.

17. The radiation-sensitive composition according to claim 13, wherein a content of the radical trapping agent with respect to 100 parts by mass of the particles is no less than 0.01 parts by mass and no greater than 20 parts by mass.

18. The pattern-forming method according to claim 13, wherein a metal atom constituting the metal oxide is at least any one of a zirconium atom, a hafnium atom, a zinc atom, a tin atom, a nickel atom, and a cobalt atom.

19. The radiation-sensitive composition according to claim 13, wherein the particles are derived from a compound represented by formula (A), a hydrolysis product or a hydrolytic condensation product thereof, or a combination of the same:
LₐMY_{b} (A)
wherein
in the formula (A),
M represents a metal atom constituting the metal oxide;
L represents a ligand;
a is an integer of 0 to 2, wherein in a case in which a is 2, a plurality of Ls are identical or different;
Y represents a hydrolyzable group selected from a halogen atom, an alkoxy group, and an acyloxy group;
b is an integer of 2 to 6, wherein a plurality of Ys are identical or different; and
L represents a ligand not falling under a category of Y.

20. The radiation-sensitive composition according to claim 13, wherein the particles comprise:
a metal atom constituting the metal oxide; and
a ligand derived from an organic acid.

21. The radiation-sensitive composition according to claim 20, wherein the particles further comprise a ligand derived from a base.

22. The radiation-sensitive composition according to claim 20, wherein the organic acid is methacrylic acid.

23. The radiation-sensitive composition according to claim 13, wherein a mean particle diameter of the particles is no greater than 20 nm.

24. The radiation-sensitive composition according to claim 13, further comprising a radiation-sensitive acid generating agent.
